(19) United States
(12) Patent Application Publication
(10) Pub. No.: US 2004/0009670 A1
(43) Pub. Date: Jan. 15, 2004

(54) Apparatus and method for reducing oxidation of polished metal surfaces in a chemical mechanical polishing process

(76) Inventors: Axel Preusse, Radebeul (DE); Gerd Marxsen, Radebeul (DE); Johannes Groschopf, Wainsdorf (DE)

Correspondence Address: J. Mike Amerson, Williams, Morgan & Amerson , P.C., Suite 1100, 10333 Richmond, Houston, TX, 77042, US

(21) Appl. No.: 10/358,787

(22) Filed: Feb. 5, 2003

(30) Foreign Application Priority Data
Jun. 28, 2002 (DE) 102 29 000.8

(51) Int. Cl. H01L 21/302; H01L 21/461

(52) U.S. Cl. 438/692

(57) ABSTRACT

During the processing of a substrate in a semiconductor production line in accordance with CMP related process steps, inert gas, such as nitrogen, is supplied to the substrate to establish a gas atmosphere surrounding the substrate, thereby significantly reducing the concentration of oxygen and/or sulfur dioxide. Conventionally, these processes are performed in an open atmosphere so that, particularly in processing copper-containing substrates, a high degree of corrosion and discoloration may be generated. By reducing oxygen and/or sulfur dioxide during these “wet” processes, the equilibrium of the involved chemical reaction is accordingly shifted so that the amount of the corrosion may be drastically reduced.

### BACKGROUND OF THE INVENTION

1. Field of the Invention

The present invention relates to the field of fabrication of integrated circuits, and, more particularly, to the chemical mechanical polishing (CMP) of substrates and processes associated therewith.

2. Description of the Related Art

The materials used in multi-level interconnect technology of integrated circuits are thin films of conductors and thin films of insulators. To manufacture conductive thin films, aluminum (Al) and aluminum alloys have been widely used in combination with silicon dioxide (SiO₂) as an insulator. To further improve device performance in view of signal propagation delay and power consumption of an integrated circuit, copper is nowadays increasingly replacing aluminum due to copper's significantly higher conductivity and increased resistance against electromigration. Currently, the so-called damascene technique is preferably employed in forming copper metallization layers of sophisticated integrated circuits. In the damascene technique, a dielectric material, for example, silicon dioxide, is patterned to form trenches and vias that are subsequently filled with copper, preferably in a plating process, as copper may not be deposited very efficiently with the required thickness by chemical or physical vapor deposition. Since the trenches have to be reliably filled with copper, a certain amount of “over-plating” has to be provided. Thus, the excess copper has to be removed from the dielectric material in a further process step. Chemical mechanical polishing (CMP) has proven to be a viable candidate and is presently the preferred method to remove the excess copper and, at the same time, planarize the surface for further processing of the substrate.

Generally, in chemical mechanical polishing, a substrate material, such as a metal, is removed by means of an abrasive in combination with one or more chemical agents that causes a chemical reaction with the material to be removed. Typically, the abrasives and the chemical agent(s) are provided in an aqueous solution in the form of a slurry that is delivered to a polishing pad. Since relatively aggressive chemical agents are commonly required to efficiently remove excess metal, the metal surface of the conductive copper structures, e.g., metal lines and contacts, may be subjected to continued chemical reaction after completion of the polishing process, especially in the presence of reactive components, such as oxygen and sulfur dioxide, thereby possibly compromising the quality of the metal lines and contacts. For example, the copper surface of the polished metal lines and vias may readily react with oxygen and sulfur dioxide in the presence of water that is provided by the aqueous slurries or by rinse water required to remove the aggressive chemical agents to form corrosion and discoloration, thereby compromising reliability and throughput of the production process.

Therefore, a need exists for an improved CMP process that allows the polishing of metal layers, especially copper layers, without unduly deteriorating the surface quality of the metal.

### SUMMARY OF THE INVENTION

The present invention is directed to a new improved CMP sequence including cleaning steps performed prior, during and after completion of the CMP process, wherein the probability of a chemical reaction of an exposed metal surface with reactive components of the ambient atmosphere, possibly in combination with the chemicals used during the polishing process, is significantly reduced by establishing a substantially inert gas atmosphere surrounding the substrate.

As used herein, the term “substantially inert gas atmosphere” is meant to denote a gas atmosphere that includes a significantly lower concentration of oxygen than the ambient atmosphere of the CMP tool, which is typically a clean room environment, wherein an oxygen concentration of the substantially inert gas atmosphere is at least 20% less than that of the ambient atmosphere. Preferably, the total amount of oxygen in the substantially inert gas atmosphere is less than 10%, and more preferably less than 1%.

According to one illustrative embodiment of the present invention, a process tool for chemically mechanically polishing a substrate comprises a polishing station and a cover enclosing the polishing station to define an internal volume containing an internal gas atmosphere, wherein the cover is configured to substantially avoid a gas exchange with an ambient atmosphere.

According to a further illustrative embodiment of the present invention, a process tool comprises at least one of a CMP station, a rinse station, a dry station, a storage station and a storage tank for chemicals. The process tool further comprises a gas supply system configured to provide a flow of inert gas to the at least one of a CMP station, a rinse station, a dry station, a storage station and a storage tank for chemicals.

According to still another illustrative embodiment of the present invention, a method of processing a substrate during a process sequence including the chemical mechanical polishing of the substrate comprises providing a process tool for a CMP-related process step. Then, a gas atmosphere is established that surrounds the substrate, wherein the gas atmosphere has a lower oxygen concentration than an ambient atmosphere surrounding the process tool.

### BRIEF DESCRIPTION OF THE DRAWINGS

The invention may be understood by reference to the following description taken in conjunction with the accompanying drawings, in which like reference numerals identify like elements, and in which:

FIG. 1 shows a Pourbaix diagram of copper;

FIG. 2 schematically shows a CMP station having a cover that allows the establishment of a substantially inert gas atmosphere according to one illustrative embodiment of the present invention;

FIG. 3 schematically shows a process tool including a CMP station, a cleaning station and a drying station according to a further embodiment of the present invention; and

FIGS. 4a-4d schematically show portions of a CMP station, in which a flow of inert gas is provided according to further illustrative embodiments of the present invention.

While the invention is susceptible to various modifications and alternative forms, specific embodiments thereof have been shown by way of example in the drawings and are herein described in detail. It should be understood, however, that the description herein of specific embodiments is not intended to limit the invention to the particular forms disclosed, but on the contrary, the intention is to cover all modifications, equivalents, and alternatives falling within the spirit and scope of the invention as defined by the appended claims.

### DETAILED DESCRIPTION OF THE INVENTION

Illustrative embodiments of the invention are described below. In the interest of clarity, not all features of an actual implementation are described in this specification. It will of course be appreciated that in the development of any such actual embodiment, numerous implementation-specific decisions must be made to achieve the developers' specific goals, such as compliance with system-related and business-related constraints, which will vary from one implementation to another. Moreover, it will be appreciated that such a development effort might be complex and time-consuming, but would nevertheless be a routine undertaking for those of ordinary skill in the art having the benefit of this disclosure.

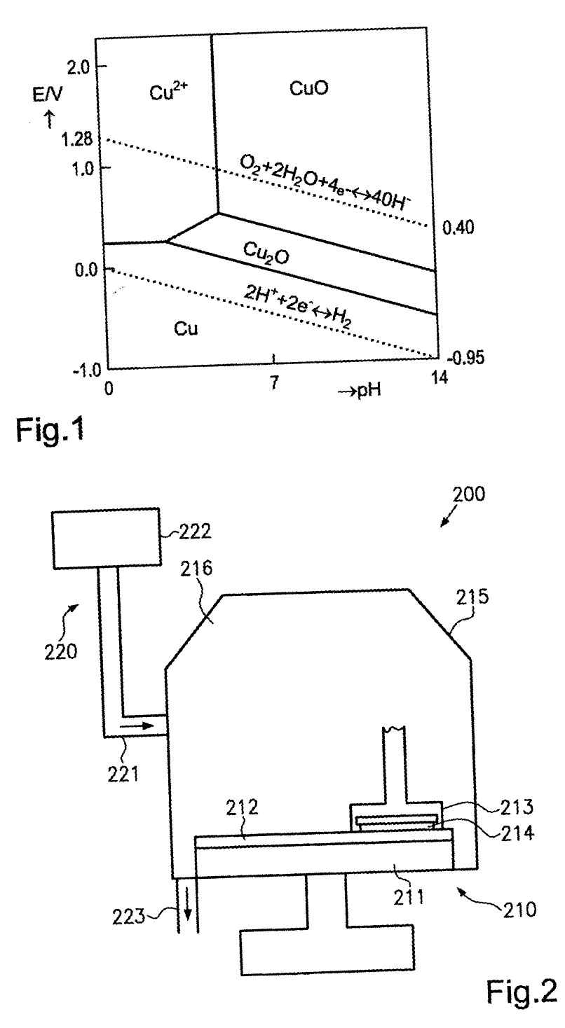

With reference to FIG. 1, the chemistry of a metal surface in contact with humidity and natural gases during and after the polishing process will now be described in more detail with reference to copper. However, the present invention should not be considered as limited to use with copper unless such limitations are expressly set forth in the appended claims.

It is well known, that copper is oxidized in air to form copper-oxide (Cu₂O). In the presence of carbon dioxide (CO₂), copper may form the so-called green copper carbonate. In the presence of sulfur dioxide (SO₂), which may be present in air, copper may form a sulfate. Therefore, a copper layer on a substrate may most likely be subjected to various oxidation processes creating copper ions (Cu⁺or Cu⁺⁺) as part of a compound according to the relations given in Equation 1a. These reactions preferably take place in the presence of oxygen and water, which are commonly also present in the ambient air.

O₂+2H₂O+4e→4OH⁻ Equation 1

2Cu→2Cu²⁺+4e Equation 1a

2H⁺+2e−→H₂ .Equation 2

Equation 1 shows the chemical reaction resulting in the so-called oxygen corrosion. The equation shows that oxygen present in air or dissolved in water leads to an oxidation process. The electrons necessary in Equation 1 are spent, for example, by the process of Equation 1a and copper is transformed to Cu²⁺.

FIG. 1 illustrates more clearly this situation in which the so-called Pourbaix diagram of copper is depicted. The Pourbaix diagram shows the electrochemical potentials of copper, its oxides, Cu₂O and CuO, and of the copper ion (Cu⁺⁺) as a function of the pH-value. The diagram shows four separate areas denoted as Cu, Cu₂O, CuO and Cu²⁺. The areas are separated by lines representing the situation of equilibrium of the compounds of the neighboring areas. The equilibrium may exist between two compounds along a line in the diagram or between three compounds around an intersection of lines separating different pairs of compounds. The redox potentials of the oxygen reduction according to Equation 1 are also shown in the Pourbaix diagram of FIG. 1. Over the entire pH area the redox potentials of the oxygen reduction are above the copper (Cu) equilibrium where Cu₂O and CuO is formed as a protective layer. As a consequence, in the presence of oxygen according to Equation 1, copper (Cu) will be oxidized to form copper oxide (CuO) or copper ions (Cu⁺⁺), depending on the pH value.

Another possible situation is demonstrated by Equation 2 and the corresponding electrochemical potential of this equation is also presented in the Pourbaix diagram of FIG. 1. The process according to Equation 2 is generally addressed as hydrogen corrosion, which takes place by reducing 2H⁺to H₂. As is known from electrochemical potentials, copper (Cu) is more noble than hydrogen. This fact is represented by the redox function of Equation 2 in the Pourbaix diagram of FIG. 1. Along the entire pH-area, the redox potential curve according to Equation 2 is within the area of elementary copper (Cu).

It has been demonstrated that, preferably in the presence of oxygen and water, an oxidation process of copper (Cu) will take place.

4CuO+SO₂+3H₂O+0,5O₂→CuSO₄.3Cu(OH)₂ Equation 3

Equation 3 shows the formation of caustic copper in the presence of sulfur dioxide (SO₂), water and oxygen. Caustic copper has a good solubility in water. Therefore, the reaction according to Equation 3 removes the copper oxide (CuO) protective layer and may cause further attack of the copper layer. In a similar way, a carbonate of copper may be produced in the presence of humidity, oxygen and carbon dioxide (CO₂).

According to the present invention, the inventors recognize the importance of minimizing the amount of oxygen and/or the amount of sulfur dioxide and/or the amount of humidity during process stages involving the handling of substrates having exposed metal areas and, in particular, exposed copper areas. As previously explained, the processes involved in chemical mechanical polishing of substrates create environmental conditions for the substrate that promote oxidation of metal surfaces. The present invention is, therefore, based on the concept of creating at least locally an ambient for a substrate to be subjected to a process sequence requiring an exposed metal surface to be contacted with water containing solutions, in which the amount of sulfur dioxide and/or oxygen is considerably reduced, to thereby shift the equilibrium in Equation 3 towards the copper oxide (left side) and to reduce the copper oxidation according to Equations 1, 1a and 2. This may be accomplished by providing a substantially inert atmosphere, i.e., to lower the partial pressure of oxygen and/or sulfur dioxide to a significantly reduced value compared to the ambient atmosphere, around the substrate to be processed by supplying substantially inert gases, such as nitrogen, argon and the like to the process tool or at least to relevant portions of the process tool.

FIG. 2 depicts an illustrative embodiment of the present invention that will now be described in detail. A process tool 200 comprises a CMP station 210 and an inert gas supply 220. The CMP station 210 comprises a polishing platen 211 having arranged thereon a polishing pad 212. A polishing head 213 is configured to receive a substrate 214 to be polished. Since other components of the CMP station are not relevant for the understanding of the present invention, further details of the CMP station 210 are not depicted in FIG. 2 and will not be described. The CMP station 210 further comprises a cover 215 that substantially encloses the polishing pad 212 so as to define an internal volume 216 containing an internal gas atmosphere therein. The cover 215 is configured to substantially prevent a gas exchange from the internal volume 216 to the ambient atmosphere surrounding the CMP station 210. By substantially preventing or avoiding a gas exchange from the internal volume 216 to the ambient atmosphere, it is meant that once the internal gas atmosphere is established in a predefined composition within the internal volume 216, a mixture with the ambient atmosphere requires a time period on the order of minutes without continuously re-establishing the internal gas atmosphere. Thus, the cover 215 does not necessarily need to be configured to completely seal the CMP station 210 from the ambient atmosphere but is configured to substantially delay the gas exchange with the ambient atmosphere. That is, the cover 215 may be configured to “loosely” surround the CMP station without requiring sealing, wherein, for example, nitrogen is supplied to continuously compensate for the “leakage” rate. In other cases, openings may be formed in the cover 215, wherein the continuously fed nitrogen creates a slight overpressure within the cover 215 and the permanent flow of nitrogen substantially hinders natural gases of the ambient atmosphere in entering the internal volume 216.

The gas supply system 220 comprises a supply line 221, one end of which is in fluid communication with the internal volume 216 and the other end thereof is connected to an inert gas source 222. The gas supply system 220 may further comprise an exhaust line 223.

In operation, the substrate 214 may be loaded onto the polishing head 213, wherein the cover 215 may be removed or may be provided with an opening (not shown) through which the substrate 214 is transferred into the CMP station 210. Next, an inert gas is supplied to the CMP station 210 via the supply line 221 to establish a substantially inert gas atmosphere in the internal volume 216. Depending on the degree of gas leakage through the cover 215, it may be necessary to discharge gas by the exhaust line 223 while feeding the inert gas by the supply line 221. While polishing the substrate 214 with the chemicals contained in the slurry, as previously explained, the significant reduction of oxygen and/or of sulfur dioxide compared to conventional CMP stations operating in an “open” atmosphere may lead to a reduced probability for the corrosion of metal surfaces, especially after completion of a polishing step or a polishing sub-step when lifting the polishing head 213 to remove the substrate from the polishing pad 212.

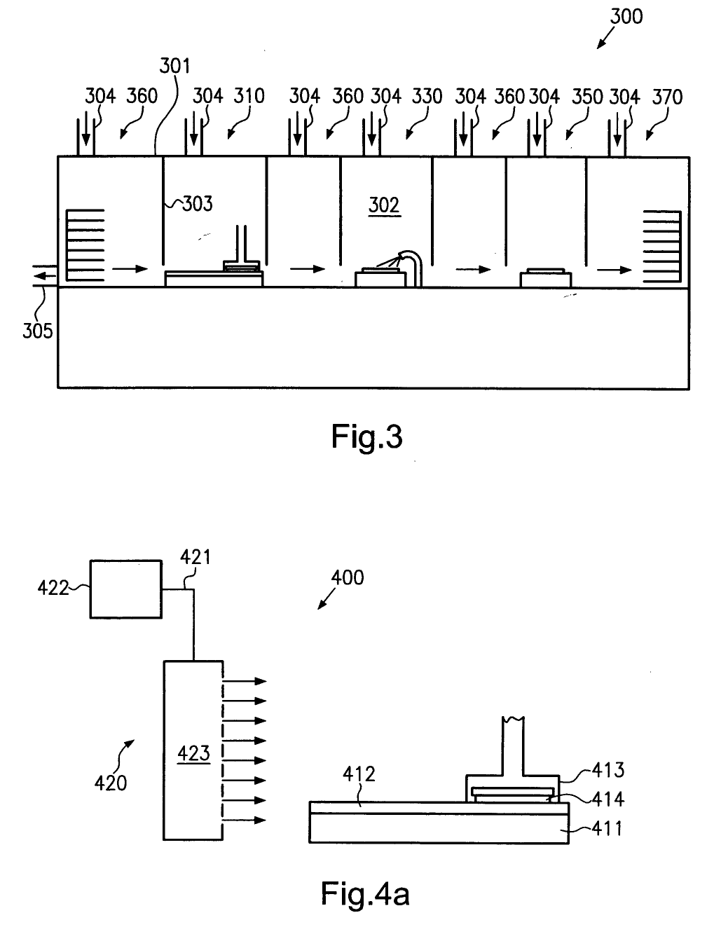

FIG. 3 schematically shows a process tool 300 including a CMP station 310, a rinse station 330, a dry station 350, a storage station 370 and a plurality of transportation modules 360. Thus, the process tool 300 is configured to carry out a CMP related process sequence, wherein the arrangements of the individual process stations and modules is depicted only in a very simplified manner to illustrate various process steps of an actual CMP process sequence. In actual CMP processes, two or more polishing sub-steps with different slurries with intermediate purge and rinse steps may be required, wherein after completion of these various CMP steps, further cleaning and rinsing processes, possibly including storing the substrates temporarily in a storage station, such as station 370, possibly including a water tank, and subsequently drying the substrates, for example, in dry station 350 are carried out. Accordingly, the process tool 300 is meant to exemplarily depict the plurality of process stations and associated transportation modules required for a complex CMP process sequence in a production line of modern integrated circuits.

The process tool 300 may further comprise one or more tanks (not shown) containing various chemical agents used for operating the CMP station 310. Moreover, a cover 301 is provided to define an internal volume 302, wherein a plurality of baffles 303 may be provided to divide the internal volume 302 into a plurality of segments with reduced gas exchange between adjacent segments. A plurality of supply lines 304 and one or more exhaust lines 305 may be provided, wherein the supply lines 304 are connected to an inert gas source (not shown) which may be a simple pressurized gas tank or which may be a chemical system that is configured to rework exhaust gas supplied by the exhaust line 305.

In operation, an inert gas, such as nitrogen, argon, or other noble gases and the like, is supplied to the internal volume 302 to establish a substantially inert gas atmosphere, thereby substantially reducing the amount of oxygen and/or sulfur dioxide that a substrate processed by the various process stations and transportation modules experiences. For example, when the substrate processed by the CMP station 310 is conveyed to the rinse station 330, the contact with oxygen and/or sulfur dioxide is drastically reduced and thus corrosion of the exposed metal surface will be significantly reduced, if not even completely avoided. Moreover, when the substrate is temporarily stored in the storage station 370 containing, for example, ultra pure water, an inert gas atmosphere is established over the water surface so that the substrate, upon loading or de-loading in and from the storage station 370, will substantially not come into contact with oxygen and/or sulfur dioxide. Furthermore, by means of the substantially inert gas atmosphere over the water surface, oxygen and/or sulfur dioxide will substantially not dissolve in the ultra pure water or will be removed from the ultra pure water due to the extremely low partial pressure of oxygen and sulfur dioxide. The same holds true for any tank of chemicals included in the process tool 300. It should be noted that ultra pure water as usually understood in the field of semiconductor production is meant to describe sterilized degassed deionized water with organic impurities substantially removed.

Since the entire CMP related process sequence including substrate transportation may be performed in the substantially inert gas atmosphere of the internal volume 302, the process of corrosion is drastically slowed down, as is previously explained with reference to FIG. 1.

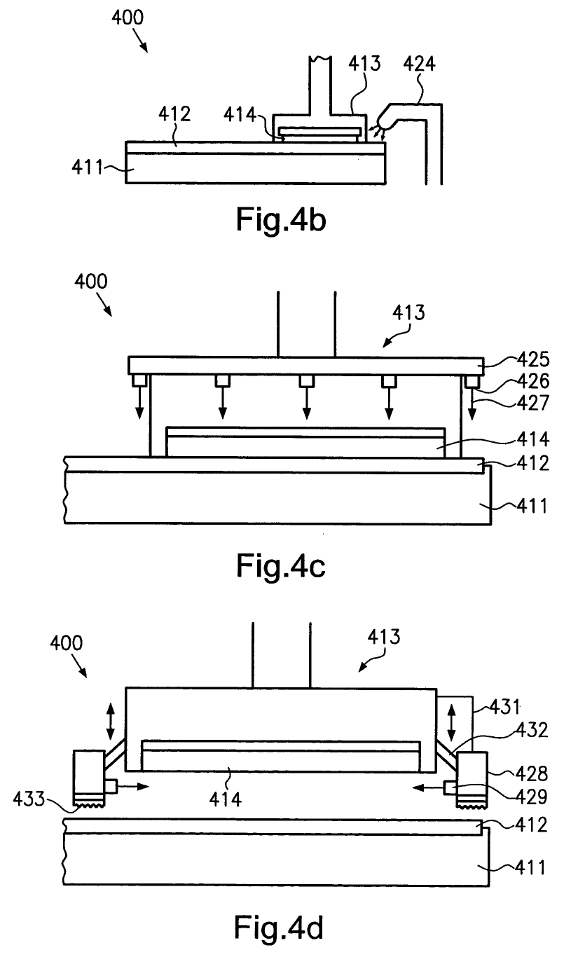

FIGS. 4a-4d schematically show relevant portions of a CMP station 400 according to further illustrative embodiments of the present invention. In FIG. 4a, a polishing platen 411, with a polishing pad 412 located thereon, is arranged adjacent to a gas supply system 420 including an inert gas source 422, a supply line 421 and a gas flow distribution element 423. A polishing head 413 is movably located on the polishing pad 412 and is configured to convey the substrate 414 to and from the polishing pad 412 and holding the substrate 414 during polishing.

During operation, the gas supply system 420 provides a stream, sometimes continuous, of inert gas via the gas distribution element 423 so that an area surrounding the polishing pad 412 and the polishing head 413, and thus the substrate 414, are in contact with the inert gas stream. In so doing, the oxygen concentration and/or a sulfur dioxide concentration is significantly reduced while handling and processing the substrate 414. Preferably, the amount of inert gas supplied to the substrate 414 during processing and handling may be adjusted, for example, by controlling the flow rate in the supply line 421, so that oxygen concentration and sulfur dioxide concentration during substrate handling is reduced to a desired value. Suitable means for providing the stream of inert gas and regulating a flow rate are well known in the art and may include any type of appropriately formed openings, nozzles and the like as well as proportional valves in combination with a pressurized gas source 422. Moreover, the size and shape of the gas flow distribution element 423 may be selected to obtain the stream of inert gas having the desired properties. For example, the gas flow distribution element 423 may comprise an array of nozzles that are arranged to provide the inert gas across the entire polishing platen 411. Furthermore, the location of the gas flow distribution element 423 may be selected in any suitable manner. For instance, the gas flow distribution element 423 may placed above the polishing platen 411.

FIG. 4b schematically shows a further illustrative embodiment, in which the CMP station 400 further comprises a nozzle 424 that is configured and positioned to supply a stream of inert gas to a specified portion of the polishing pad 412. This allows the selective provision of a stream of inert gas to relevant portions of the CMP station 400. For example, the nozzle 424 may be positioned to provide the stream of inert gas when the substrate 414 is loaded or de-loaded to and from the polishing head 413 to substantially avoid contact to the ambient atmosphere.

FIG. 4c schematically shows a further illustrative embodiment, wherein the polishing head 413 further comprises a gas supply manifold 425 having gas supply nozzles 426 that are configured to supply gas jets 427. The gas supply manifold 425 may be supplied with an inert gas by one of the supply lines provided within the polishing head 413. The manifold 425 may have any appropriate shape and size. In one embodiment, the manifold 425 may have, at least partially, a ring-shaped configuration.

Thus, in operation, the substrate 414 experiences an atmosphere of reduced oxygen and/or sulfur dioxide and corrosion of exposed metal surfaces may be reduced. The inert gas atmosphere surrounding the substrate 414 may reduce, if not even completely avoid, oxidation of the exposed metal surfaces, especially after completion of the CMP process, when the substrate 414 is lifted from the polishing pad 412 and the water containing slurry still forms a thin film on the polished surface.

FIG. 4d schematically shows a further illustrative embodiment in which the polishing head 413 comprises a movable nozzle ring 428 with nozzles 429 that are configured to provide a gas jet inwardly with respect to the polishing head 413. The nozzle ring 428 is vertically movably supported by a lever 432 and a flexible supply line 431 is connected to the polishing head 413 and the nozzle ring 428 to provide inert gas thereto.

In operation, the polishing head 413 may be lifted to receive the substrate 414, wherein the nozzle ring 428 moves to a lower position, for example, simply by gravity or any other appropriate actuating means well known in the art, to provide a stream of inert gas inwardly while the substrate 414 is received by the polishing head 413. Upon lowering the polishing head 413 to the polishing pad 412, the nozzle ring 428 will be pushed upwardly or may be actuated by an appropriate actuator into an upper position (relative to the polishing head 413) so that the nozzle ring 428 is substantially flush with or above the polishing pad 412 and will not adversely affect the operation of the polishing head 413.

In another embodiment, the nozzle ring 428 may advantageously be used as a so-called pad conditioning element. To this end, the nozzle ring 428 may comprise a conditioning surface 433 made of an appropriate material and having a surface texture that allows conditioning of the polishing pad 412. During the polishing of the substrate 414, the stream of inert gas from the nozzles 429 may be discontinued or may be maintained depending on process requirements. After completion of the CMP process, when the polishing head 413 is lifted, the nozzle ring 428 moves into the lower position and will provide a substantially inert gas atmosphere at the surface of the substrate 414 that is still coated by a thin film of slurry. In one embodiment, the nozzles 429 may be provided only over a portion of the nozzle ring 428, for example, over a half of the nozzle ring 428, so as to establish a substantially laminar stream along the surface of the substrate 414 during loading and de-loading. Similarly, the number and the size of the nozzles 429 may be arbitrarily selected so long as the substrate surface is sufficiently purged by the inert gas stream. Thus, in some embodiments, it may be sufficient to provide only one nozzle 429.

It should be noted that the embodiments described with reference to FIGS. 4a-4d may be used in any combination and may also be used in combination with the embodiments described with reference to FIGS. 2 and 3.

As a result, the present invention allows the establishment of an atmosphere around a substrate in a CMP related process sequence such that the partial pressure of oxygen and/or sulfur dioxide and/or other natural gases is significantly reduced so that the probability of an adverse chemical reaction with exposed metal surfaces is reduced, thereby allowing improved throughput and reliability of the fabrication process. Moreover, the present invention is to enclose all types of process tools involved in a CMP process, irrespective whether such tools are stand-alone tools or are provided as integrated units unifying a plurality of process steps.

The particular embodiments disclosed above are illustrative only, as the invention may be modified and practiced in different but equivalent manners apparent to those skilled in the art having the benefit of the teachings herein. For example, the process steps set forth above may be performed in a different order. Furthermore, no limitations are intended to the details of construction or design herein shown, other than as described in the claims below. It is therefore evident that the particular embodiments disclosed above may be altered or modified and all such variations are considered within the scope and spirit of the invention. Accordingly, the protection sought herein is as set forth in the claims below.

What is claimed:

1. A process tool for treating a substrate containing an exposed metal surface, comprising:
a CMP station; and
a cover enclosing said CMP station to define an internal volume containing an internal gas atmosphere, wherein said cover is configured to substantially avoid a gas exchange with an ambient atmosphere.

2. The process tool of claim 1, further comprising a gas supply system configured to introduce an inert gas into the internal volume to establish a substantially inert gas atmosphere in said internal volume.

3. The process tool of claim 1, further comprising at least one of a transportation module, a rinsing station, a dry station, a substrate storage station and a chemical storage tank.

4. The process tool of claim 2, wherein said inert gas comprises at least one of nitrogen gas and a noble gas.

5. The process tool of claim 2, wherein said gas supply system comprises a plurality of inlet lines to provide said inert gas to at least one specified location within the internal volume.

6. The process tool of claim 3, wherein the cover is configured to divide the internal volume into a plurality of segments, wherein a gas exchange between adjacent volume segments is reduced.

7. The process tool of claim 2, wherein said gas supply system is configured to establish a continuous inert gas flow at least in a portion of said process tool.

8. The process tool of claim 7, wherein said CMP station comprises a polishing pad and a polishing head and wherein said gas supply system comprises a gas distribution system configured to provide said continuous inert gas flow to said polishing pad and said polishing head.

9. The process tool of claim 7, wherein said CMP station comprises a polishing pad and a polishing head and wherein said gas supply system comprises a gas nozzle configured and arranged to provide said continuous inert gas flow to a specified area of said polishing pad.

10. The process tool of claim 1, wherein the CMP station comprises a polishing head including a nozzle rim having at least one nozzle for providing a flow of inert gas.

11. The process tool of claim 1, wherein said CMP station comprises a polishing head including a nozzle element that is movably attached to a periphery of the polishing head, wherein said nozzle element is movable from a first position to a second position, wherein the nozzle element is configured to provide an inert gas stream to a substrate receiving portion of said polishing head when being in the second position.

12. The process tool of claim 11, wherein said nozzle element comprises a conditioning surface that allows the conditioning of a polishing pad when the nozzle element is in the second position.

13. A process tool, comprising:
at least one of a CMP station, a rinse station, a dry station, a storage station and a storage tank for chemicals; and
a gas supply system configured to provide a flow of inert gas to said at least one of a CMP station, a rinse station, a dry station, a storage station and a storage tank for chemicals.

14. The process tool of claim 13, wherein said gas supply system comprises an inert gas source including at least one of nitrogen and a noble gas.

15. The process tool of claim 13, further comprising a polishing pad and a polishing head, wherein the gas supply system further comprises a gas distribution element configured to provide said flow of inert gas to the polishing pad and the polishing head.

16. The process tool of claim 13, further comprising a polishing pad and a polishing head, wherein the gas supply system further comprises a nozzle element configured and arranged to supply said flow of inert gas to a specified area of the polishing pad.

17. The process tool of claim 13, further comprising a polishing pad and a polishing head, wherein the gas supply system is coupled to the polishing head and includes a nozzle rim having at least one nozzle element to provide a flow of inert gas.

18. The process tool of claim 13, further comprising a polishing head and a polishing pad, wherein said polishing head comprises a nozzle element movably attached to the polishing head and operatively coupled to said gas supply system, wherein said nozzle element is movable from a first position to a second position and the nozzle element is adapted and arranged to provide a flow of inert gas to a substrate receiving portion of said polishing head when in the second position.

19. The process tool of claim 18, wherein said nozzle element comprises a plurality of nozzles arranged along at least a portion of a periphery of said polishing head.

20. The process tool of claim 18, wherein said nozzle element comprises a conditioning surface that allows conditioning of the polishing pad when the nozzle element is in the second position.

21. The process tool of claim 13, further comprising a cover defining an internal volume and configured to reduce a gas exchange from the internal volume to an ambient atmosphere.

22. The process tool of claim 20, further comprising at least one transportation module.

23. The process tool of claim 21, wherein said cover is configured to divide said internal volume into at least a first segment corresponding to said transportation module and a second segment, wherein a gas exchange between the first segment and the second segment is reduced.

24. The process tool of claim 22, wherein said gas supply system comprises a first supply line and a second supply line to supply said inert gas to the first and second segments, respectively.

25. A method of processing a substrate during a process sequence including the chemical mechanical polishing of the substrate, the method comprising:
providing a process tool for a CMP related process step; and
establishing a gas atmosphere surrounding said substrate, wherein said gas atmosphere has a lower oxygen concentration than an ambient atmosphere surrounding said process tool.

26. The method of claim 25, wherein establishing said gas atmosphere includes supplying an inert gas to the substrate.

27. The method of claim 26, wherein said inert gas comprises at least one of nitrogen and a noble gas.

28. The method of claim 25, wherein establishing said gas atmosphere includes defining an internal volume by providing a cover surrounding said process tool that reduces a gas exchange of the gas atmosphere with the ambient atmosphere.

29. The method of claim 25, wherein said process tool comprises a polishing pad and a polishing head and wherein establishing said gas atmosphere includes supplying a gas flow of inert gas to at least a portion of said polishing pad.

30. The method of claim 25, wherein said process tool comprises a rinse station and establishing said gas atmosphere includes supplying a flow of inert gas to said substrate during the rinsing of the substrate.

31. The method of claim 29, wherein establishing said gas atmosphere includes providing a cover to define an internal volume and supply an inert gas to said internal volume.

32. The method of claim 25, wherein said process tool is a substrate storage station and establishing said gas atmosphere includes supplying a flow of inert gas to said substrate.

33. The method of claim 31, wherein said storage station includes a pure water reservoir and establishing said gas atmosphere includes supplying inert gas over said pure water reservoir.

34. The method of claim 25, wherein said process tool is a chemical storage tank and establishing said gas atmosphere includes providing an inert gas atmosphere in said chemical storage tank.
